(19) United States
(12) Patent Application Publication
(10) Pub. No.: US 2025/0384913 A1
(43) Pub. Date: Dec. 18, 2025

(54) MEMORY WITH MEMORY CELL INITIALIZATION CIRCUITRY, AND ASSOCIATED SYSTEMS, DEVICES, AND METHODS

(71) Applicant: Micron Technology, Inc., Boise, ID (US)

(72) Inventors: Jing Wen, Taichung (TW); Debra M. Bell, Boise, ID (US); Bo Sheng Zheng, Taichung (TW); Chen-Whai Sheng, Taichung (TW)

(21) Appl. No.: 19/222,484

(22) Filed: May 29, 2025

Related U.S. Application Data
(60) Provisional application No. 63/661,290, filed on Jun. 18, 2024.

(51) Int. Cl. G11C 11/4072

(52) U.S. Cl. CPC G11C 11/4072

(57) ABSTRACT

Memory with memory cell initialization circuitry is disclosed herein. In one embodiment, a memory device includes a plurality of memory cells, each memory cell coupled to a corresponding word line of a plurality of word lines and a corresponding bit line of a plurality of bit lines. The memory device can receive an indication to enter a fast deterministic initialization mode. Based at least in part on the indication, the memory device can (a) control one or more first switches coupled to the word lines to drive voltages on the word lines toward a first voltage such that storage elements of the memory cells are coupled to the bit lines, and (b) control one or more second switches coupled to the bit lines to drive voltages on the bit lines toward a second voltage such that the storage elements are written to a deterministic data state.

### CROSS-REFERENCE TO RELATED APPLICATIONS

The present application claims priority to U.S. Provisional Patent Application No. 63/661,290, filed June 18, 2024, the disclosure of which is incorporated herein by reference in its entirety.

This application contains subject matter related to an U.S. Patent Application by Jing Wen et al. titled “MEMORY WITH DATA DESTRUCTION CIRCUITRY, AND ASSOCIATED SYSTEMS, DEVICES, AND METHODS.” The related application is assigned to Micron Technology, Inc., and is identified as U.S. Patent Application No. 63/661,212, filed June 18, 2024. The subject matter thereof is incorporated herein by reference thereto.

### TECHNICAL FIELD

The present disclosure generally relates to semiconductor devices. For example, several embodiments of the present disclosure are directed to memory devices with memory cell initialization circuitry that can initialize memory cells to a (e.g., desired) deterministic data state, and associated systems, devices, and methods.

### BACKGROUND

Memory devices are widely used to store information related to various electronic devices such as computers, wireless communication devices, cameras, digital displays, and the like. Memory devices are frequently provided as internal, semiconductor, integrated circuits, and/or external removable devices in computers or other electronic devices. There are many different types of memory, including volatile and non-volatile memory. Volatile memory, including static random-access memory (SRAM), dynamic random-access memory (DRAM), and synchronous dynamic random-access memory (SDRAM), among others, may require a source of applied power to maintain its data. Non-volatile memory, by contrast, can retain its stored data even when not externally powered. Non-volatile memory is available in a wide variety of technologies, including flash memory (e.g., NAND and NOR) phase change memory (PCM), ferroelectric random-access memory (FeRAM), resistive random-access memory (RRAM), and magnetic random-access memory (MRAM), among others. Improving memory devices, generally, may include increasing memory cell density, increasing read/write speeds or otherwise reducing operational latency, increasing reliability, increasing data retention, reducing power consumption, or reducing manufacturing costs, among other metrics.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1A is a partially schematic block diagram of a memory system configured in accordance with various embodiments of the present technology.

FIG. 1B is a partially schematic block diagram of a memory device configured in accordance with various embodiments of the present technology.

FIG. 2 illustrates is a partially schematic diagram of memory cell initialization circuitry coupled to a word line driver and a memory array, all of which are configured in accordance with various embodiments of the present technology.

FIG. 3 is a flowchart illustrating a method for initializing memory cells in accordance with various embodiments of the present technology.

FIG. 4 is a schematic view showing a system comprising a semiconductor device assembly that can include memory devices configured in accordance with various embodiments of the present technology.

### DETAILED DESCRIPTION

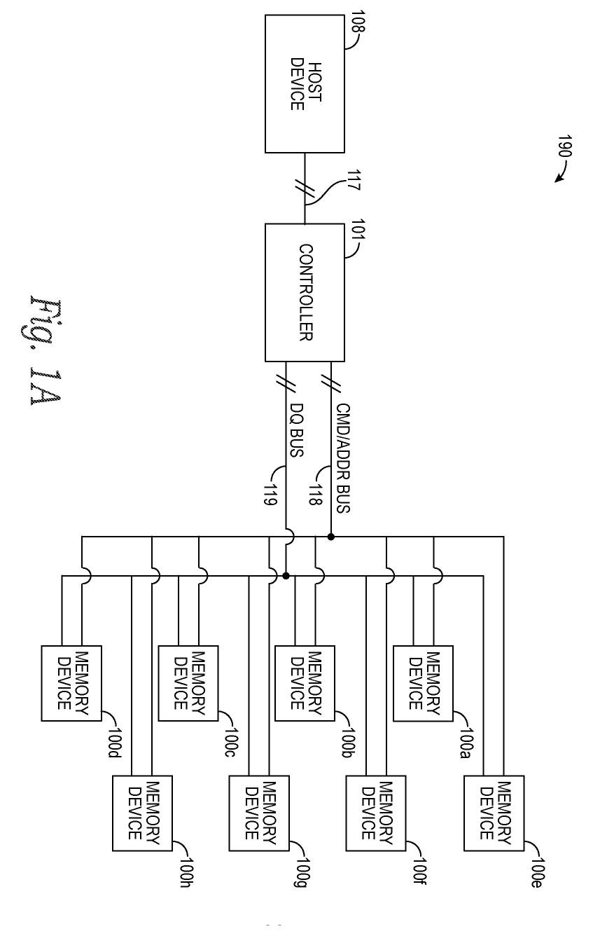

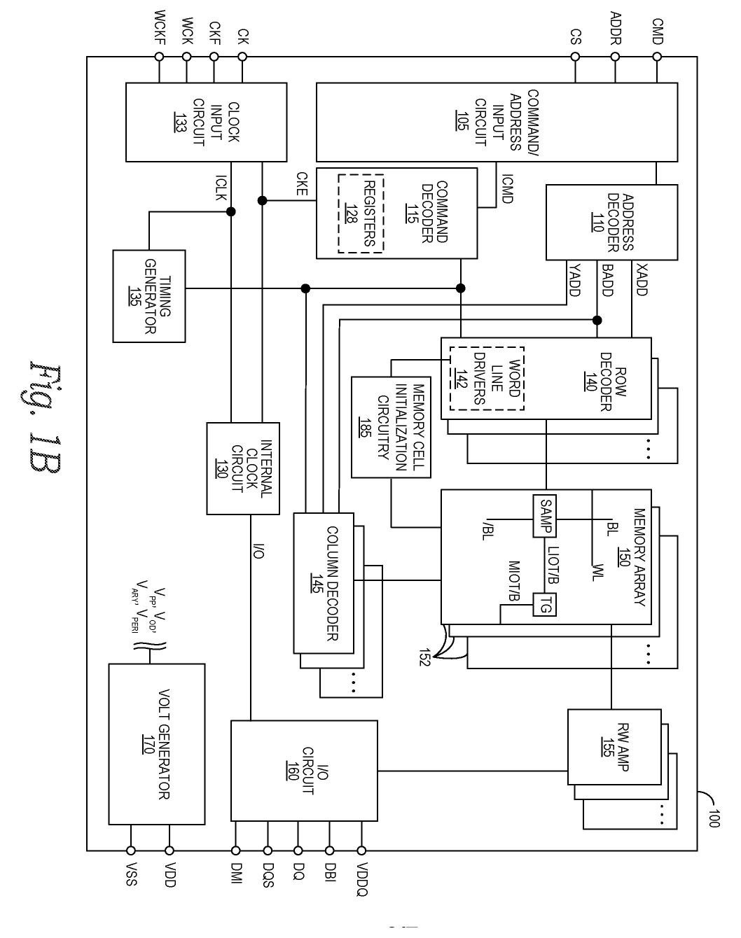

The present disclosure is generally directed to memory with memory cell initialization circuitry and associated systems, devices, and methods. For example, several embodiments described in detail below are directed to memory devices that are configured to receive an indication (or to detect when) to enter a fast deterministic initialization mode. The indication can indicate that memory cells of the memory devices are to be written/initialized to a deterministic data state, such as a first data state (e.g., corresponding to a logical one) or a second data state (e.g., corresponding to a logical zero). Based at least in part on the indication, the memory devices can (a) drive word lines corresponding to the memory cells to a voltage that is usable to couple storage elements of the memory cells to corresponding bit lines, (b) drive the corresponding bit lines to a second voltage that corresponds to the deterministic data state, and (c) charge or discharge the storage elements via the corresponding bit lines such that the storage elements are written/initialized to the deterministic data state. A person skilled in the art will understand that the technology may have additional embodiments and that the technology may be practiced without several of the details of the embodiments described below with reference to FIGS. 1A–4.

In the illustrated embodiments below, the memory devices and systems are primarily described in the context of devices incorporating DRAM storage media. Memory devices configured in accordance with other embodiments of the present technology, however, can include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media.

### A. Overview

Semiconductor memory devices may store information in an array of memory cells. The information may be stored as a binary code, and each memory cell may store a bit of information as either a logical high (e.g., a “1”) or a logical low (e.g., a “0”). The memory cells may be organized at the intersection of word lines (rows) and bit lines (columns). The memory may further be organized into one or more memory banks, each of which may include a plurality of rows and columns. During operations, the memory device may (a) receive a command and an address which specifies one or more rows and one or more columns and (b) execute the command on the memory cells corresponding to the address.

Memory devices can benefit from being able to quickly charge or discharge their memory cells to a deterministic data state (e.g., a readable data state, an interpretable data state, a desired data state), such as a logic level ‘0’ or a logic level ‘1.’ For example, configuring the memory cells to a deterministic data state can have practical benefits such as conditioning the memory device for certain subsequent operations. In some cases, the ability to charge or discharge memory cells to a deterministic data state quickly can be required by the industry, such as by JEDEC or other standards. In other cases, the ability to quickly initialize memory cells to a deterministic data state may be useful for preventing or hindering unauthorized access to data stored to the memory cells.

Recognizing these benefits, the inventors have developed semiconductor devices (and associated systems, devices, and methods) that can quickly initialize all or a subset of memory cells to a deterministic data state. For example, in accordance with one aspect of the present technology, a memory device (or other apparatus) can include memory cell initialization circuitry for initiating all or a subset of memory cells of a memory device to one or more deterministic data states (e.g., a first deterministic data state corresponding to a logical high and/or a second deterministic data state corresponding to a logical low). More specifically, the memory device can include a memory array with a plurality of memory cells, a plurality of word lines, and a plurality of bit lines. Each memory cell can be coupled to a corresponding word line of the plurality of word lines and a corresponding bit line of the plurality of bit lines. The memory device can further include a plurality of word line drivers coupled to the plurality of word lines, and memory cell initialization circuitry. The memory cell initialization circuitry can include (a) one or more first switches that selectively couple the plurality of word lines to a first voltage source (e.g., a voltage source configured to supply a voltage Vpp), (b) one or more second switches that selectively couple the plurality of bit lines to a second voltage source (e.g., a voltage source configured to supply a voltage Vdd) and/or a third voltage source (e.g., a voltage source configured to supply a voltage Vss).

In some embodiments, the memory cell initialization circuitry can be enabled and/or operate while the memory device enters/operates within a fast deterministic initialization mode. For example, the memory device can receive an indication (e.g., a command or information programmed into one or more mode registers of the memory device) to enter a fast deterministic initialization mode. The indication can be an indication to enter a first fast deterministic initialization mode that corresponds to, for example, initializing all or a subset of memory cells to the first deterministic data state. Additionally, or alternatively, the indication can be an indication to enter a second fast deterministic initialization mode that corresponds to, for example, initializing all or a subset of memory cells to the second deterministic data state.

Based at least in part on the memory device receiving an indication to enter a fast deterministic initialization mode, the memory cell initialization circuitry can control the one or more first switches to selectively couple the plurality of word line drivers to the first voltage source such that (a) voltages on the plurality of word lines are driven toward a first voltage and (b) storage elements of the memory cells are coupled to the plurality of bit lines. In addition, the memory cell initialization circuitry can control the one or more second switches to selectively couple the plurality of bit lines to either the second voltage source or the third voltage source (e.g., depending on whether the indication to enter the fast deterministic initialization mode is an indication to enter the first fast deterministic initialization mode or an indication to enter the second fast deterministic initialization mode). In turn, the storage elements of the memory cells can be initialized (e.g., charged or discharged)via the plurality of bit line to a deterministic data state (e.g., a logical one or a logical zero) that corresponds to the second voltage source or the third voltage source that is coupled to the plurality of bit lines.

The present technology is therefore expected to offer several advantages. For example, the present technology is expected to facilitate initializing (e.g., charging or discharging) memory cells to one or more deterministic data states quickly and reliably. In addition, circuitry of the present technology that can be employed for enabling a memory device to quickly initiate memory cells to a deterministic data state is relatively minimal and low in cost to implement.

### B. Selected Embodiments of Memory Systems and Associated Devices and Methods

FIG. 1A is a block diagram schematically illustrating a memory system 190 (e.g., a dual in-line memory module (DIMM)) configured in accordance with various embodiments of the present technology. In the illustrated embodiment, the memory system 190 includes a module or rank of memory devices 100 (identified individually as memory devices 100a–100h in FIG.1A), a controller 101, and a host device 108. In some embodiments, the memory devices 100 can be DRAM memory devices. Although illustrated with a single module/rank of eight memory devices 100 in FIG.1A, the memory system 190 can include a greater or lesser number of memory devices 100 and/or memory modules/ranks in other embodiments of the present technology. Well-known components of the memory system 190 have been omitted from FIG. 1A and are not described in detail below so as to avoid unnecessarily obscuring aspects of the present technology.

The memory devices 100 can be connected to one or more electronic devices that are capable of utilizing memory for temporary or persistent storage of information, or a component thereof. For example, one or more of the memory devices 100 can be operably connected to one or more host devices. As a specific example, the memory devices 100 of the memory system 190 illustrated in FIG. 1A are connected to a host device 101 (also referred to herein as a “memory controller 101” or a “control circuit 101”) and to a host device 108 (also referred to herein as “CPU 108”).

The memory devices 100 of FIG. 1A are operably connected to the memory controller 101 via a command/address (CMD/ADDR) bus 118 and a data (DQ) bus 119. As described in greater detail below with respect to FIG. 1B, the CMD/ADDR bus 118 and the DQ bus 119 can be used by the memory controller 101 to communicate commands, memory addresses, and/or data to the memory devices 100. In response, the memory devices 100 can execute commands received from the memory controller 101. For example, in the event a write command is received from the memory controller 101 over the CMD/ADDR bus 118, the memory devices 100 can receive data from the memory controller 101 over the DQ bus 119 and can write the data to memory cells corresponding to memory addresses received from the memory controller 101 over the CMD/ADDR bus 118. As another example, in the event a read command is received from the memory controller 101 over the CMD/ADDR bus 118, the memory devices 100 can output data to the memory controller 101 over the DQ bus 119 from memory cells corresponding to memory addresses received from the memory controller 101 over the CMD/ADDR bus 118.

The host device 108 of FIG. 1A may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device 108 may be a networking device (e.g., a switch, a router, etc.); a recorder of digital images, audio, and/or video; a vehicle; an appliance; a toy; or any one of a number of other products. In one embodiment, the host device 108 may be connected directly to one or more of the memory devices 100 (e.g., via a communications bus of signal traces (not shown)). Additionally, or alternatively, the host device 108 may be indirectly connected to one or more of the memory device 100 (e.g., over a networked connection or through intermediary devices, such as through the memory controller 101 and/or via a communications bus 117 of signal traces).

As discussed further herein, each of the memory devices 100 can include circuitry (also referred to herein as “memory cell initialization circuitry,” “initialization circuitry,” “data initialization circuitry,” and the like) for initializing memory cells of the respective memory device 100 to one or more (e.g., desired) deterministic data states, such as a first data state (e.g., a high or ‘1’ data state) and/or a second data state (e.g., a low or ‘0’ data state). In some embodiments, the circuitry can be enabled and/or operated while the respective memory device 100 is in a fast deterministic initialization mode. The respective memory device 100 can enter the fast deterministic initialization mode upon powerup or initialization of the respective memory device, at the direction of a command (e.g., received from a connected host device, such as the memory controller 101 and/or the host device 108), and/or at another timing or upon the occurrence of another event.

FIG. 1B is a block diagram schematically illustrating one of the memory devices 100 configured in accordance with various embodiments of the present technology. The memory device 100 may include an array of memory cells, such as memory array 150. The memory array 150 may include a plurality of banks 152 (e.g., banks 0–15 in the example of FIG. 1B), and each bank may include a plurality of word lines (WL), a plurality of bit lines (BL), and a plurality of memory cells (e.g., m × n memory cells) arranged at intersections of the word lines (e.g., m word lines, which may also be referred to as rows) and the bit lines (e.g., n bit lines, which may also be referred to as columns).

Memory cells can include any one of a number of different memory media types, including capacitive, phase change, magnetoresistive, ferroelectric, or the like. The selection of a word line WL may be performed by a row decoder 140, and the selection of a bit line BL may be performed by a column decoder 145. Sense amplifiers (SAMP) may be provided for corresponding bit lines BL and connected to at least one respective local I/O line pair (LIOT/B), which may in turn be coupled to at least one respective main I/O line pair (MIOT/B), via transfer gates (TG), which can function as switches. The memory array 150 may also include plate lines and corresponding circuitry for managing their operation.

The memory device 100 may employ a plurality of external terminals that include command and address terminals coupled to a command bus and address bus (e.g., the CMD/ADDR bus 118 of FIG. 1A) to receive command signals CMD and address signals ADDR, respectively. The memory device may further include a chip select terminal to receive a chip select signal CS, clock terminals to receive clock signals CK and CKF; data clock terminals to receive data clock signals WCK and WCKF; data terminals to receive data signals DQ, DQS or RDQS, DBI (for data bus inversion function), and DMI (for data mask inversion function); and power supply terminals to receive power supply potentials VDD, VSS, and VDDQ.

The power supply potentials VDD and VSS can be supplied to an internal voltage generator circuit 170. The internal voltage generator circuit 170 can generate various internal potentials VPP, VOD, VARY, VPERI, and the like based on the power supply potentials VDD and VSS. The internal potential VPP can be used in the row decoder 140, the internal potentials VOD and VARY can be used in the sense amplifiers included in the memory array 150, and the internal potential VPERI can be used in many other circuit blocks.

The power supply potential VDDQ can be provided to an input/output circuit 160 of the memory device 100, together with the power supply potential VSS. The power supply potential VDDQ can be the same potential as the power supply potential VDD in some embodiments of the present technology. The power supply potential VDDQ can be a different potential from the power supply potential VDD in other embodiments of the present technology. The dedicated power supply potential VDDQ can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 133. The CK and CKF signals can be complementary, and the WCK and WCKF signals can be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 133 can receive the external clock signals. For example, when enabled by a CKE signal from a command decoder 115 of the memory device 100, an input buffer can receive the CK and CKF signals and the WCK and WCKF signals. The clock input circuit 133 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK received from the clock input circuit 133 and the clock enable signal CKE received from the command decoder 115.

For example, the internal clock circuit 130 can include a clock path (not shown in FIG. 1B) that receives the internal clock signal ICLK and provides various clock signals to the command decoder 115. The internal clock circuit 130 can further provide input/output (I/O) clock signals. The I/O clock signals can be supplied to the input/output circuit 160 and can be used as a timing signal for determining an output timing of read data and an input timing of write data. The I/O clock signals can be provided at multiple clock frequencies so that data can be output from and input into the memory device 100 at different data rates. A higher clock frequency may be desirable when high memory speed is desired. A lower clock frequency may be desirable when lower power consumption is desired. The internal clock signals ICLK can also be supplied to a timing generator 135 that can generate various internal clock signals.

The command terminals and address terminals may be supplied with an address signal and a bank address signal from outside the memory device 100. The address signal and the bank address signal supplied to the address terminals can be transferred, via a command/address input circuit 105, to an address decoder 110. The address decoder 110 can receive the address signals and supply a decoded row address signal (XADD) to the row decoder 140 (which may be referred to as a row driver), and a decoded column address signal (YADD) to the column decoder 145 (which may be referred to as a column driver). The address decoder 110 can also receive the bank address portion of the ADDR input and supply the decoded bank address signal (BADD) to both the row decoder 140 and the column decoder 145.

The command and address terminals may be supplied with command signals CMD, address signals ADDR, and chip select signals CS, from a memory controller. The command signals may represent various memory commands received from the memory controller (e.g., refresh commands, activate commands, precharge commands, access commands, which can include read commands and write commands). The select signal CS may be used to select the memory device 100 to respond to commands and addresses provided to the command and address terminals. When an active CS signal is provided to the memory device 100, the commands and addresses can be decoded and memory operations can be performed. The command signals CMD may be provided as internal command signals ICMD to the command decoder 115 via the command/address input circuit 105.

The command decoder 115 may include circuits to decode the internal command signals ICMD to generate various internal signals and commands for performing memory operations (e.g., a row command signal to select a word line and a column command signal to select a bit line). Other examples of memory operations that the memory device 100 may perform based on decoding the internal command signals ICMD includes a refresh command (e.g., re-establishing full charges stored in individual memory cells of the memory array 150), an activate command (e.g., activating a row in a particular bank, in some cases for subsequent access operations), or a precharge command (e.g., deactivating the activated row in the particular bank). The internal command signals can also include output and input activation commands, such as clocked command CMDCK (not shown in FIG. 1B).

The command decoder 115, in some embodiments, may further include one or more registers 128 for tracking various counts and/or values (e.g., counts of refresh commands received by the memory device 100 or self-refresh operations performed by the memory device 100) and/or for storing various operating conditions for the memory device 100 to perform certain functions, features, and modes (or test modes). As such, in some embodiments, the registers 128 (or a subset of the registers 128) may be referred to as mode registers. Additionally, or alternatively, the memory device 100 may include registers 128 as a separate component outside of the command decoder 115. In some embodiments, the registers 128 may include multi-purpose registers (MPRs) configured to write and/or read specialized data to and/or from the memory device 100.

When a read command is issued to a bank with an open row and a column address is timely supplied as part of the read command, read data can be read from memory cells in the memory array 150 designated by the row address (which may have been provided as part of the activate command identifying the open row) and column address. The read command may be received by the command decoder 115, which can provide internal commands to an input/output circuit 160 so that read data can be output from the data terminals DQ, DQS or RDQS, DBI, and DMI via read/write amplifiers 155 and the input/output circuit 160 according to the DQS or RDQS clock signals. The read data may be provided at a time defined by read latency information that can be programmed in the memory device 100, for example, in a mode register (e.g., one or more of the registers 128). The read latency information can be defined in terms of clock cycles of the clock signal CK. For example, the read latency information can be a number of clock cycles of the clock signal CK after the read command is received by the memory device 100 when the associated read data is provided.

When a write command is issued to a bank with an open row and a column address is timely supplied as part of the write command, write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160, and supplied via the input/output circuit 160 and the read/write amplifiers 155 to the memory array 150. The write data may be written in the memory cell designated by the row address and the column address. The write data may be provided to the data terminals at a time that is defined by write latency information. The write latency information can be programmed in the memory device 100, for example, in a mode register (e.g., one or more of the registers 128). The write latency information can be defined in terms of clock cycles of the clock signal CK. For example, the write latency information can be a number of clock cycles of the clock signal CK after the write command is received by the memory device 100 when the associated write data Is received.

In the illustrated embodiment, the row decoder 140 includes a plurality of word line drivers 142 (also referred to herein as “word line driver circuits,” “WL drivers,” “WL driver circuits,” “driver circuitry,” and the like) operably coupled to the memory array 150. Although shown as part of the row decoder 140 in FIG. 1B, the word line drivers 142 can be located elsewhere in the memory device 100 in other embodiments of the present technology. Each word line of the memory array 150 may be coupled with a corresponding word line (WL) driver 142 configured to control a voltage of the word line during memory operations.

As shown, the memory device 100 further includes memory cell initialization circuitry 185 operably coupled to the word line drivers 142 and to the memory array 150. Although shown outside of the row decoder 140 and the memory array 150 in FIG. 1B, the memory cell initialization circuitry 185 can be positioned at one or more other locations in other embodiments of the present technology. For example, all or a subset of the memory cell initialization circuitry 185 can be included in the row decoder 140, the memory array 150, and/or in other components of the memory device 100.

As discussed further herein, the memory cell initialization circuitry can be enabled and/or operated while the memory device 100 is in a fast deterministic initialization mode. In some embodiments, the memory device 100 can enter a fast deterministic initialization mode (e.g., automatically) upon powerup or initialization of the memory device 100, such as following a power down event or a power loss event of the memory device 100. In these and other embodiments, the memory device 100 can enter a fast deterministic initialization mode upon receipt of a corresponding command (e.g., from a connected host device, such as the memory controller 101 and/or the host device 108). In these and still other embodiments, the memory device 100 can enter a fast deterministic initialization mode at another timing or upon the occurrence of another event. As a specific example, a fast deterministic initialization mode of the memory device 100 can be enabled via a set feature option of the memory device 100 and/or by programming mode registers (e.g., one or more of the registers 128) of the memory device 100. As another example, a fast deterministic initialization mode can be enabled (e.g., automatically) when an internal temperature of the memory device drops below a threshold temperature value. The threshold temperature value can be predetermined and/or set at a temperature value below which it is likely that an attempt to gain access of the stored data without authorization is occurring. For example, the predetermined threshold can be set at a temperature value below internal temperature values of the memory device 100 that are typically observed within the memory device 100 during standard operation or use of the memory device 100, and/or at or below a temperature value that indicates the memory device 100 is likely being cooled to delay and/or prevent the memory device 100 from irretrievably losing stored data as it is swapped between systems. As still another example, the memory device 100 can enter a fast deterministic initialization mode to initialize all or a subset of the memory cells to a (e.g., desired) data state, such as prior to writing data to the memory cells, after a predetermined amount of time has elapsed since the memory cells were last accessed, and/or upon the occurrence of another event.

When the memory device 100 is operating in the fast deterministic initialization mode, the memory cell initialization circuitry 185 can control the word line drivers 142 to drive voltages on the word lines WL to a first voltage (e.g., a voltage Vdd, a voltage Vpp, a voltage Vccp, or another suitable voltage level). As discussed in greater detail below, the first voltage can be a voltage level that is high enough to access memory cells of the memory array 150 and couple storage elements of the memory cells to corresponding bit line BL of the memory array 150. Additionally, or alternatively, when the memory device is operating in the fast deterministic initialization mode, the memory cell initialization circuitry 185 can drive voltages on the bit lines BL to a second voltage or a third voltage that, when the storage elements of the memory cells are coupled to the corresponding bit lines BL, charge or discharge the storage elements of the memory cells to a deterministic data state (e.g., a first data state or a second data state, such as (a) a high or ‘1’ data state or (b) a low or ‘0’ data state). In other words, the memory cell initialization circuitry 185 of the memory device 100 can be used during the fast deterministic initialization mode to quickly initialize memory cells of the memory array 150 to a deterministic data state.

In some embodiments, the memory device 100 can have multiple fast deterministic initialization modes. For example, the memory device 100 can have a first fast deterministic initialization mode (also referred to herein as a “first data state fast deterministic initialization mode,” a “fast one initialization mode,” “a fast one mode,” and the like) and a second fast deterministic initialization mode (also referred to herein as a “second data state fast deterministic initialization mode,” a “fast zero initialization mode,” “a fast zero mode,” and the like). When the memory device 100 is placed and operated in the first fast deterministic initialization mode, the memory cell initialization circuitry 185 can be operated to initialize memory cells of the memory array 150 to a first data state (e.g., a high or ‘1’ data state). Additionally, or alternatively, when the memory device 100 is placed and operated in the second fast deterministic initialization mode, the memory cell initialization circuitry 185 can be operated to initialize memory cells of the memory array 150 to a second data state (e.g., a low or ‘0’ data state). In some embodiments, the memory device 100 can enter either the first fast deterministic initialization mode or the second fast deterministic initialization mode (e.g., automatically and/or by default) upon powerup or initialization of the memory device 100 (e.g., following a power down event or a power loss event of the memory device 100) or at another timing or upon the occurrence of another event, such as when an internal temperature of the memory device 100 drops below a threshold temperature value.

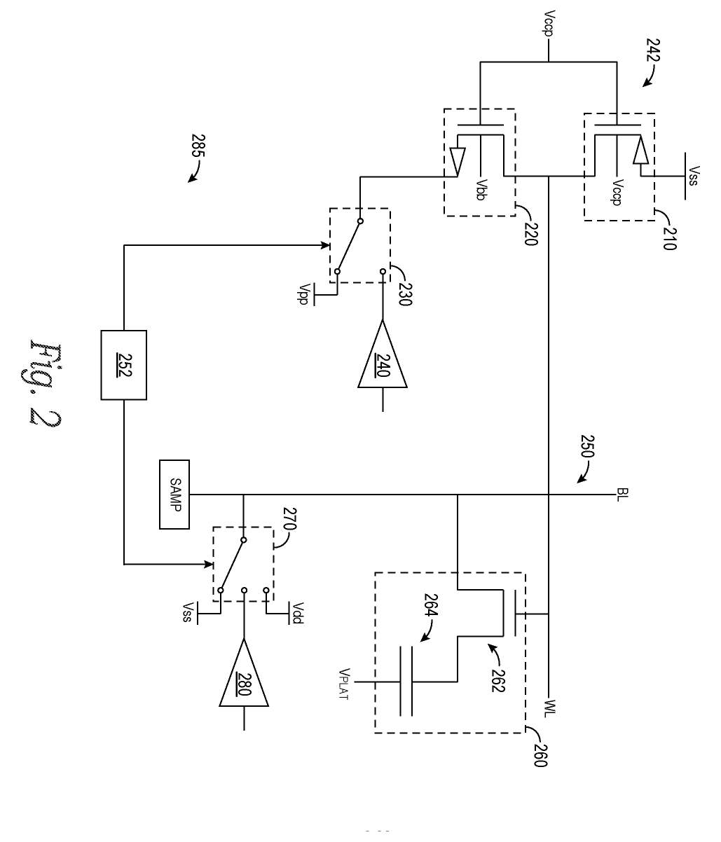

FIG. 2 is a partially schematic diagram of memory cell initialization circuitry 285 coupled to a word line driver 242 (or a portion thereof) and a memory array 250 (or a portion thereof), all of which are configured in accordance with various embodiments of the present technology. The memory cell initialization circuitry 185 can be the memory cell initialization circuitry 185 of FIG. 1B or other memory cell initialization circuitry configured in accordance with various embodiments of the present technology. Additionally, or alternatively, the word line driver 242 can be one of the word line drivers 142 of FIG. 1B or another word line driver configured in accordance with various embodiments of the present technology.

In the illustrated embodiment, the word line driver 242 includes a complementary metal-oxide-semiconductor (CMOS) inverter having a first transistor 210 (e.g., a p-type metal-oxide-semiconductor (PMOS) transistor), a second transistor 220 (e.g., an n-type metal-oxide-semiconductor (NMOS) transistor), an input coupled to the gates of the first transistor 210 and the second transistor 220, and an output coupled to the drain terminals of the first transistor 210 and the second transistor 220. The source terminal of the first transistor 210 can be coupled to a voltage source Vss, the body terminal of the first transistor 210 can be coupled to a voltage source Vccp, the input of the inverter can be coupled to the voltage source Vccp, the body terminal of the second transistor 220 can be coupled to a voltage source Vbb, and the output of the inverter can be coupled to a word line WL.

The source terminal of the second transistor 220 can be coupled to a first switch 230 of the memory cell initialization circuitry 285. As shown, the first switch 230 can be configured to couple the source terminal of the second transistor 220 (and hence the word line WL when the second transistor 220 is activated) to either (a) a negative word line voltage (Vnwl) generator 240 or (b) a first voltage source, such as a voltage source Vpp, a voltage source Vdd, a voltage source Vccp, or another suitable voltage source. In the illustrated embodiment, the first switch 230 is shown as a single pole double throw (SPDT) switch. In other embodiments, the first switch 230 can have other configurations. For example, the first switch 230 can comprise a transistor (e.g., a PMOS transistor) coupled between the word line WL and the Vnwl generator 240, and a transistor (e.g., an NMOS transistor) coupled between the word line WL and the voltage source Vpp. Continuing with this example, the gates of the two transistors can be coupled together and/or each receive a control signal usable to selectively activate the two transistors.

In some embodiments, the memory cell initialization circuitry 285 further includes a switch controller 252 configured to control operation of the first switch 230. In one example, the switch controller 252 can comprise a pulse generator configured to generate a pulse in a control signal that is usable to toggle the first switch 230 between states. The control signal provided by the switch controller 252 can have multiple states, such as a high state and a low state. Continuing with this example, when the control signal is in the high state, the first switch 230 can couple the source terminal of the second transistor 220 (and hence the word line WL when the second transistor 220 is activated) to the first voltage source (e.g., shown as the voltage source Vpp in FIG. 2). Furthermore, when the control signal is in the low state, the first switch 230 can couple the source terminal of the second transistor 220 (and hence the word line WL when the second transistor 220 is activated) to the Vnwl generator 240. In other embodiments, the response of the first switch 230 to the high and low states of the control signal can be flipped. It is appreciated that the memory cell initialization circuitry 285 can include multiple instances of the first switch 230 in some embodiments of the present technology that are each controllable (collectively or individually) via the switch controller 252.

Referring now to the memory array 250, the memory array 250 can include a plurality of memory cells. One such memory cell 260 is shown in FIG. 2. As shown, the memory cell 260 is positioned at an intersection of the word line WL and a bit line BL. The memory cell 260 can include a capacitor 264 (or other suitable storage element) and an access transistor 262 coupled between the capacitor 264 and the bit line BL. One plate of the capacitor 264 can be coupled to the access transistor 262, and the other plate of the capacitor 264 can be coupled to a voltage source Vplat, a ground voltage source (e.g., voltage source Vss), or another suitable voltage source. A gate terminal of the access transistor 262 can be coupled to the word line WL such that a voltage on the word line WL can be used to selectively activate the access transistor 262 to couple the capacitor 264 to the bit line BL. Although only one memory cell 260 of the memory array 250 is shown in FIG. 2, it is appreciated (a) that the memory array 250 can include several instances of such memory cells and (b) that aspects of the present technology described above and below with respect to the memory cell 260 illustrated in FIG. 2 can equally apply to the other memory cells of the memory array 250.

In the illustrated embodiment, the memory cell initialization circuitry 285 further includes a second switch 270 coupled to the bit line BL. The second switch 270 can be configured to selectively couple the bit line BL to (a) a second voltage source (e.g., a voltage source Vdd or another suitable voltage source), (b) a third voltage source (e.g., a voltage source Vss or another suitable voltage source), or (c) a bit line precharge voltage (Vblp) generator 280. In the illustrated embodiment, the second switch 270 is shown as a single pole triple throw (SPTT) switch. In other embodiments, the second switch 270 can have other configurations. For example, the second switch 270 can comprise a transistor coupled between the bit line BL and the Vblp generator 280, a transistor coupled between the bit line BL and the voltage source Vdd, and a transistor coupled between the bit line BL and the voltage source Vss. Continuing with this example, the gates of these transistors can each be configured to receive a respective control signal that is usable to selectively activate the respective transistor.

Although shown as configured to selectively couple the bit line BL to (a) the second voltage source, (b) the third voltage source, or (c) the Vblp generator 280, the switch 270 in other embodiments of the present technology can be configured to selectively couple the bit line BL to (a) the Vblp generator 280 or (b) either (e.g., only one of) the second voltage source or the third voltage source. In such embodiments, the second switch 270 can include a single pole double throw (SPDT) switch or another suitable configuration.

Referring again to the illustrated embodiment, the switch controller 252 can be configured to control operation of the second switch 270, such as using a same or similar pulse generator (not shown) and/or control signal(s) to toggle the second switch 270 between states. For example, when a control signal output by the switch controller 252 is in a low state, the second switch 270 can couple the bit line BL to the Vblp generator 280. In some embodiments, the low state of the control signal can correspond to the memory device 100 operating outside of a fast deterministic initialization mode. Additionally, or alternatively, when a control signal output by the switch controller 252 is in a high state, the second switch 270 can couple the bit line BL to either the second voltage source or the third voltage source. In some embodiments, the high state of the control signal can correspond to the memory device 100 operating in a fast deterministic initialization mode. As a specific example, a corresponding memory device may include a first fast deterministic initialization mode and a second fast deterministic initialization mode. Continuing with this example, when the memory device is operating in the first fast deterministic initialization mode, the switch controller 252 can be configured to output the control signal in the high state, and the second switch 270 can (based at least in part on the control signal) couple the bit line BL to the second voltage source (shown as the voltage source Vdd in FIG. 2). On the other hand, when the memory device is operating in the second fast deterministic initialization mode, the switch controller 252 can be configured to output the control signal in the high state, and the second switch 270 can (based at least in part on the control signal) couple the bit line BL to the third voltage source (shown as the voltage source Vss in FIG. 2). In other embodiments, the switch controller 252 can be configured to output multiple control signals or a control signal with more than two states. In these embodiments, the control signal(s) can be used to control the second switch 270 to selectively couple the bit line BL to a desired one of the second voltage source, the third voltage source, and the Vblp generator 280. It is appreciated that the memory cell initialization circuitry 285 can include multiple instances of the second switch 270 in some embodiments of the present technology that are controllable (collectively or individually) via the switch controller 252.Additionally, or alternatively, although the same switch controller 252 is shown in FIG. 2 as controlling both the first switch 230 and the second switch 270, it is appreciated that the memory cell initialization circuitry 285 can include a switch controller and/or pulse generator (not shown) for the second switch 270 that is separate from the switch controller 252 and/or pulse generator for the first switch 230. The switch controller and/or pulse generator for the second switch 270 can be configured to control operation of the second switch 270 independently of the switch controller 252 and/or pulse generator for the first switch 230.

Operation of the memory cell initialization circuitry 285 will now be described. When a corresponding memory device is operating outside of a fast deterministic initialization mode and/or under normal operations, the switch controller 252 can (a) configure the first switch 230 to couple the source terminal of the second transistor 220 to the Vnwl generator 240 and/or (b) configure the second switch 270 to couple the bit line BL to the Vblp generator 280. When a fast deterministic initialization mode of a corresponding memory device is enabled (e.g., when the memory device is placed/operated in (or enters) a fast deterministic initialization mode), the switch controller 252 can configure the first switch 230 to (a) uncouple the source terminal of the second transistor 220 from the Vnwl generator 240 and (b) couple the source terminal of the second transistor 220 to the first voltage source (e.g., the voltage source Vpp), as shown in FIG. 2. As discussed above, in some embodiments, the memory device can enter a fast deterministic initialization mode (e.g., automatically) upon powerup or initialization of the memory device, such as following a power down event or a power loss event of the memory device. In these and other embodiments, the memory device can enter a fast deterministic initialization mode upon receipt of a corresponding input or command (e.g., from a connected host device, from a user, etc.). For example, the memory device can enter a fast deterministic initialization mode according to information programmed into mode registers of the memory device. In these and still other embodiments, the memory device can enter a fast deterministic initialization mode at another timing or upon the occurrence of another event, such as when a set feature option of the memory device is enabled, when an internal temperature of the memory device drops below a threshold temperature value, prior to writing data to the memory cells, after a predetermined amount of time has elapsed since the memory cells were last accessed, and/or upon the occurrence of another event. In any event, when the first switch 230 is operated to couple the first voltage source to the source terminal of the second transistor 220 of the word line driver 242, the word line driver 242 can drive a voltage on the word line WL toward a first voltage (e.g., a voltage Vpp or another suitable voltage) that is usable to activate the access transistor 262 of the memory cell 260. As the access transistor 262 of the memory cell 260 is activated, the capacitor 264 of the memory cell 260 can be coupled to the bit line BL.

Additionally, when a fast deterministic initialization mode of the memory device is enabled, the switch controller 252 can configure the second switch 270 to (a) uncouple the bit line BL from the Vblp generator 280 and (b) couple the bit line BL to either the second voltage source (e.g., the voltage source Vdd) or the third voltage source (e.g., the voltage source Vss). As discussed above, the memory device can include multiple fast deterministic initialization modes (e.g., a first fast deterministic initialization mode and a second fast deterministic initialization mode). In such embodiments, the switch controller 252 can configured the second switch 270 to couple either the second voltage source or the third voltage source to the bit line BL depending on which of the multiple fast deterministic initialization modes is enabled. For example, a first fast deterministic initialization mode can correspond to a first deterministic data state (e.g., a high or ‘1’ deterministic data state). Thus, when the first fast deterministic initialization mode of the memory device is enabled, the switch controller 252 can configure the second switch 270 to couple the bit line BL to the second voltage source (shown as the voltage source Vdd in FIG. 2), which can drive a voltage on the bit line BL toward a second voltage (e.g., a voltage Vdd, 1 V, 3.3 V, 5 V, or another suitable voltage level) corresponding to the first deterministic data state. As a result, when the access transistor 262 of the memory cell 260 is activated and the capacitor 264 of the memory cell 260 is coupled to the bit line BL, the capacitor 264 can be charged or driven toward the second voltage (thereby writing the capacitor 264 to the first deterministic data state or a logic level ‘1’). Continuing with this example, a second fast deterministic initialization mode of the memory device can correspond to a second deterministic data state (e.g., a low or ‘0’ deterministic data state). Thus, when the second fast deterministic initialization mode of the memory device is enabled, the switch controller 252 can configure the second switch 270 to couple the bit line BL to the third voltage source (shown as the voltage source Vss), as shown in FIG. 2. In turn, the voltage on the bit line BL can be driven toward a third voltage (e.g., a voltage Vss, 0 V, or another suitable voltage level) corresponding to the second deterministic data state. As a result, when the access transistor 262 of the memory cell 260 is activated and the capacitor 264 of the memory cell 260 is coupled to the bit line BL, the capacitor 264 of the memory cell 260 can be discharged or driven toward the third voltage (thereby writing the capacitor 264 to the second deterministic data state or a logic level ‘0’).

As discussed above, in some embodiments, the switch controller 252 can include one or more pulse generators. In these embodiments, when the memory device 100 enters a fast deterministic initialization mode, the pulse generator(s) can generate pulses in one or more control signals output by the switch controller 252 that are usable (a) to configure the first switch 230 to couple the source terminal of the second transistor 220 to the first voltage source and/or (b) configure the second switch 270 to couple the bit line BL to the second voltage source or the third voltage source (e.g., depending on which of the fast deterministic initialization modes is/are enabled). Continuing with this example, the lengths or durations of the generated pulses can vary depending on (i) an amount of time it is expected to take to write all memory cells 260 of the memory array 250 and/or of the memory device to the corresponding deterministic data state; (ii) voltage levels supplied by the first, second, and/or third voltage sources; (iii) operating conditions such as temperature variations; and/or (iv) one or more other conditions. For example, the length of a pulse can be configured to account for a possibility that all of the memory cells 260 start from a same logic level and must be fully discharged or charged to an opposite logic level.

Once one or more amounts of time (e.g., one or more predetermined amounts of time, such as one or more amounts of time expected to be suitable for adequately writing all of the memory cells 260 to a deterministic state) has/have elapsed since coupling the capacitor 264 to the bit line BL, the switch controller 252 can operate the first switch 230 to (a) uncouple the source terminal of the second transistor 220 from the first voltage source and (b) couple the source terminal of the second transistor 220 to the Vnwl generator 240. Additionally, or alternatively, the switch controller 252 can operate the second switch 270 to (a) uncouple the bit line BL from the second voltage source or the third voltage source and (b) couple the bit line BL to the Vblp generator 280. For example, the switch controller 252 can toggle the first switch 230 after maintaining the voltage on the word line WL at the first voltage for a first predetermined period, can toggle the second switch 270 after maintaining the voltage on the bit line BL at the second voltage for a second predetermined period, and can toggle the second switch 270 after maintaining the voltage on the bit line BL at the third voltage for a third predetermined period. The first, second, and/or third predetermined periods can be the same or different from one another. In embodiments in which the switch controller 252 includes one or more pulse generators, the first switch 230 and/or the second switch 270 can be toggled at a back edge (e.g., a falling edge) of a pulse provided by the pulse generator(s). As another example, the first switch 230 and/or the second switch 270 can be toggled as the corresponding memory device begins receiving commands from a connected host device, at an end of or at another point within the memory device’s initialization routine, as an internal temperature of the memory device returns to at or above a predetermined temperature value, or upon the occurrence of one or more other events. Thereafter, the memory device can be operated as normal (e.g., in a normal operational state), such as by writing data to or reading data from the memory cells 260 of the memory array 250.

Although the embodiment of FIG. 2 is described above as using the second switch 270 to couple the bit line BL to either the second voltage source (the voltage source Vdd) or the third voltage source (the voltage source Vss) when a fast deterministic initialization mode of the memory device is enabled, a corresponding memory device can include multiple instances of the second switch 270 and multiple instances of the memory cell 260. In such embodiments, all of the second switches 270 can be operated collectively such that all of the memory cells 260 are written to a same deterministic data state when a fast deterministic initialization mode of the memory device is enabled (e.g., by controlling all of the second switches 270 to couple all of the corresponding bit lines BL to the same voltage source, such as the second voltage source or the third voltage source). Alternatively, at least some of the second switches 270 can be operated individually and/or independently. In these embodiments, all of the memory cells 260 can be written to a same deterministic data state (e.g., by controlling all of the second switches 270 to couple all of the corresponding bit lines BL to the same voltage source, such as the second voltage source or the third voltage source), or a first subset of the memory cells 260 can be written to a first deterministic data state (e.g., by controlling a corresponding first subset of the second switches 270 to couple a corresponding first subset of the bit lines BL to the second voltage source) and a second subset of the memory cells can be written to a second deterministic data state (e.g., by controlling a corresponding second subset of the second switches 270 to couple a corresponding second subset of the bit lines BL to the third voltage source).

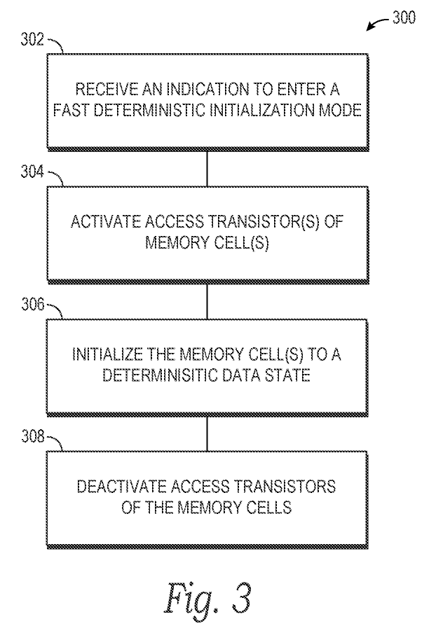

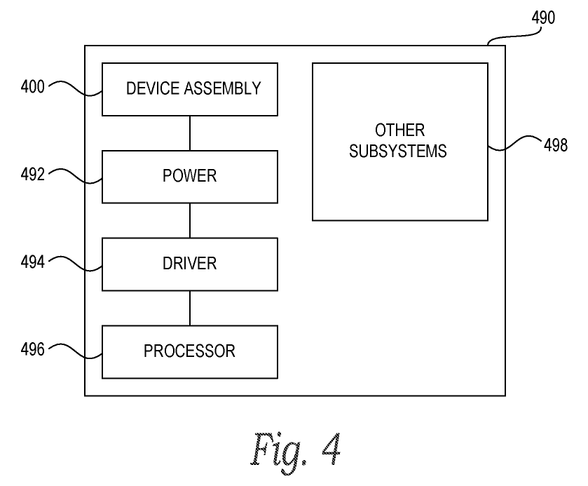

FIG. 3 is a flowchart illustrating a method 300 for initializing memory cells in accordance with various embodiments of the present technology. The method 300 is illustrated as a set of steps or blocks 302, 304, 306, and 308. All or a subset of one or more of the blocks 302, 304, 306, and/or 308 can be executed in accordance with the discussion above and/or with the discussion of FIG. 4 below.

The method 300 begins at block 302 by receiving an indication to enter a fast deterministic initialization mode. In some embodiments, the indication is received by a memory device including a plurality of word lines, a plurality of bit lines, and a plurality of memory cells arranged at intersections of the plurality of word lines with the plurality of bit lines. In some embodiments, receiving the indication can include receiving an input or a command for the memory device to enter a fast deterministic initialization mode. For example, the memory device can enter a fast deterministic initialization mode according to information programmed into mode registers of the memory device and/or according to information include in commands received at command CMD terminals of the memory device. In these and other embodiments, receiving the indication can include receiving an indication (or otherwise determining) that the memory device has experienced a power down event or a power loss event. In these and still other embodiments, receiving the indication can include receiving an indication (or otherwise determining) that the memory device is performing an initialization routine. Additionally, or alternatively, receiving the indication can include receiving an indication that a set feature option of the memory device is enabled, that an internal temperature of the memory device has dropped below a threshold temperature value, that memory cells of the memory device are to be written with user data, after a predetermined amount of time has elapsed since memory cells were last accessed, and/or at another timing or upon the occurrence of another event. In some embodiments, the indication to enter a fast deterministic initialization mode can include an indication of which fast deterministic initialization mode to enter. For example, the indication can include an indication to enter a first fast deterministic initialization mode (e.g., to initialize memory cells to a first data state, such as a high data state or logic level ‘1’). As another example, the indication can include an indication to enter a second fast deterministic initialization mode (e.g., to initialize memory cells to a second data state, such as a low data state or logic level ‘0’).

At block 304, the method 300 continues by activating access transistor(s) of memory cell(s) of the memory device. Activating the access transistor(s) can include driving one or more corresponding word line(s) toward a first voltage. The first voltage can be a voltage level sufficient to activate the access transistor(s) of the memory cell(s). Driving the corresponding word line(s) toward the first voltage can include driving the corresponding word line(s) toward the first voltage using one or more corresponding word line driver(s). Additionally, or alternatively, driving the corresponding word line(s) toward the first voltage can include controlling one or more first switches to couple the corresponding word line driver(s) to a first voltage source (e.g., a voltage source Vpp, a voltage source Vccp, a voltage source Vdd, or another suitable voltage source). In some embodiments, controlling the first switch(es) comprises (a) controlling the first switch(es) using one or more switch controllers and/or (b) configuring one or more pulse generator(s) operably coupled to the first switch(es) to generate one or more pulses (e.g., one or more high pulses). In these embodiments, the first switch(es) can couple the corresponding word line driver(s) to the first voltage source based at least in part on (or in response to) the pulse(s). Activating the access transistor(s) can include coupling one or more capacitors or other storage elements of the memory cell(s) to one or more corresponding bit lines.

At block 306, the method 300 continues by initializing the memory cell(s) to a deterministic data state. Initializing the memory cell(s) can include initializing the memory cells to a deterministic data state corresponding to the fast deterministic initialization mode of block 302. For example, in the event the fast deterministic initialization mode of block 302 is a first deterministic initialization mode and/or corresponds to a first deterministic data state (e.g., a high data state or logic level ‘1’), initialization the memory cell(s) can include initializing the memory cell(s) to the first deterministic data state. Initializing the memory cell(s) to the first deterministic data state can include controlling a second switch to couple corresponding bit line(s) to a second voltage source (e.g., a voltage source Vdd or another suitable voltage source) and driving voltages on the corresponding bit line(s) to a second voltage (e.g., a voltage Vdd or another suitable voltage) that corresponds to the first deterministic data state. Additionally, or alternatively, initializing the memory cell(s) to the first deterministic data state can include (a) charging—or increasing voltage(s) stored on—the capacitor(s)/storage element(s) of a first subset of the memory cell(s) via the corresponding bit line(s) and/or (b) discharging—or decreasing voltage(s) stored on—capacitor(s)/storage element(s) of a second subset of the memory cell(s) via the corresponding bit line(s).

As another example, in the event the fast deterministic initialization mode of block 302 is a second deterministic initialization mode and/or corresponds to a second deterministic data state (e.g., a low data state or logic level ‘0’), initialization the memory cell(s) can include initializing the memory cell(s) to the second deterministic data state. Initializing the memory cell(s) to the second deterministic data state can include controlling a second switch to couple corresponding bit line(s) to a third voltage source (e.g., a voltage source Vss or another suitable voltage source) and driving voltages on the corresponding bit line(s) to a third voltage (e.g., a voltage Vss or another suitable voltage) that corresponds to the second deterministic data state. Additionally, or alternatively, initializing the memory cell(s) to the second deterministic data state can include (a) discharging—or decreasing voltage(s) stored on—capacitor(s)/storage element(s) of a first subset of the memory cell(s) via the corresponding bit line(s), and/or (b) charging—or increasing voltage(s) stored on—the capacitor(s)/storage element(s) of a second subset of the memory cell(s) via the corresponding bit line(s).

In some embodiments, controlling the second switch(es) comprises (a) controlling the second switch(es) using one or more switch controllers and/or (b) configuring one or more pulse generator(s) operably coupled to the second switch(es) to generate one or more pulses (e.g., one or more high pulses). In these embodiments, the second switch(es) can couple the corresponding bit line(s) to the second voltage source or the third voltage source based at least in part on (or in response to) the pulse(s). The switch controller(s) and/or pulse generator(s) used to control the second switch(es) can be the same switch controller(s) and/or pulse generator(s) as—or different switch controller(s) and/or pulse generator(s) from—the switch controller(s) and/or pulse generator(s) used to control the first switch(es) discuss above with reference to block 304. Additionally, or alternatively, the one or more pulses used to control the second switch(es) can be the same pulse(s) as—or different pulse(s) from—the one or more pulses used to control the first switch(es).

At block 308, the method 300 continues by deactivating the access transistor(s) of the memory cell(s). Deactivating the access transistor(s) can include driving the corresponding word line(s) toward a fourth voltage. Driving the corresponding word line(s) toward the fourth voltage can include driving the corresponding word line(s) toward the fourth voltage using the corresponding word line driver(s). Additionally, or alternatively, driving the corresponding word line(s) to the fourth voltage can include controlling the first switch(es) to couple the corresponding word line driver(s) to a fourth voltage source. In some embodiments, the fourth voltage source can be a generator, such as a Vnwl generator. In these and other embodiments, controlling the first switch(es) can include controlling the first switch(es) after a (e.g., predetermined) first period of time has elapsed, such as an amount of time that starts from when the access transistor(s) are activated and/or that is expected to be suitable for adequately writing all or a subset of the memory cell(s) to a deterministic data state corresponding to the fast deterministic initialization mode of block 302.

In some embodiments, the method 300 can additionally include (at block 308) driving the corresponding bit line(s) toward a fifth voltage. Driving the corresponding bit line(s) toward the fifth voltage can include controlling the second switch(es) to couple the corresponding bit line(s) to a fifth voltage source. In some embodiments, the fifth voltage source can be a generator, such as a Vblp generator. In these and other embodiments, controlling the second switch(es) can include controlling the second switch(es) after a (e.g., predetermined) second period of time has elapsed, such as an amount of time that starts from when the access transistor(s) are activated and/or that is expected to be suitable for adequately writing all or a subset of the memory cell(s) to a deterministic data state corresponding to the fast deterministic initialization mode of block 302.

Although the blocks 302, 304, 306, and 308 of the method 300 are discussed and illustrated in a particular order, the method 300 illustrated in FIG. 3 is not so limited. In other embodiments, the method 300 can be performed in a different order. In these and other embodiments, all or a subset of any one or more of the blocks 302, 304, 306, and/or 308 of the method 300 can be performed before, during, and/or after all or a subset of any one or more of the other blocks 302, 304, 306, and/or 308 of the method 300. For example, the second switch(es) can be controlled to drive the bit line(s) to the second voltage or the third voltage (block 306) before, during, or after controlling the first switch(es) to drive the word line(s) to the first voltage. Moreover, a person of ordinary skill in the relevant art will recognize that the illustrated method 300 can be altered and still remain within these and other embodiments of the present technology. For example, one or more of the blocks 302, 304, 306, and 308 of the method 300 illustrated in FIG. 3 can be omitted and/or repeated in some embodiments.

FIG. 4 is a schematic view showing a system 400 comprising a semiconductor device assembly 402 that can include memory devices configured in accordance with an embodiment of the present technology. Semiconductor device assemblies including the memory devices described above with reference to FIGS. 1A–3 can be incorporated into any of a myriad of larger and/or more complex systems, such as the system 400 illustrated. The system 400 can include the semiconductor device assembly 402 (e.g., or a discrete semiconductor device), a power source 404, a driver 406, a processor 408, and/or other subsystems or components 410. The semiconductor device assembly 402 can include memory devices with features generally similar to those of the memory devices described above with reference to FIGS. 1A–3, such as the first switch 230, the Vnwl generator 240, the second switch 270, the Vblp generator 280, and the switch controller 252. The resulting system 400 can perform any of a wide variety of functions, such as memory storage, data processing, and/or other suitable functions. Accordingly, representative systems 400 can include, without limitation, hand-held devices (e.g., mobile phones, tablets, digital readers, and digital audio players), computers, vehicles, appliances, and other products. Components of the system 400 may be housed in a single unit or distributed over multiple, interconnected units (e.g., through a communications network). The components of the system 400 can also include remote devices and any of a wide variety of computer readable media. As discussed herein, the semiconductor device assemblies with memory devices configured in accordance with embodiments of the present technology are expected to quickly and reliably initialize (e.g., charge or discharge) memory cells to one or more deterministic data states with circuitry that is relatively easy to implement.

### Conclusion

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A memory device, comprising:
a memory array including a plurality of word lines, a plurality of bit lines, and a plurality of memory cells arranged at intersections of the plurality of word lines with the plurality of bit lines;
a plurality of word line drivers each coupled to a corresponding one of the plurality of word lines; and
memory cell initialization circuitry including a plurality of first switches each coupled to a corresponding one of the plurality of word line drivers and configured to selectively couple the corresponding one of the plurality of word line drivers to a first voltage source, and a plurality of second switches each coupled to a corresponding one of the plurality of bit lines and configured to selectively couple the corresponding one of the plurality of bit lines to a second voltage source, wherein the memory cell initialization circuitry is configured to, upon the memory device receiving an indication to enter a fast deterministic initialization mode, (i) couple the plurality of word line drivers to the first voltage source via the plurality of first switches such that (a) a voltage on each of the plurality of word lines is driven toward a first voltage and (b) a storage element of each of the plurality of the memory cells is coupled to a corresponding one of the plurality of bit lines, and (ii) couple the plurality of bit lines to the second voltage source via the plurality of second switches such that (1) a voltage on each of the plurality of bit lines is driven toward a second voltage corresponding to a deterministic data state and (2) the storage element of each of the plurality of memory cells is charged or discharged via the corresponding one of the plurality of bit lines to the deterministic data state.

2. The memory device of claim 1, wherein the second voltage is a voltage Vdd or the deterministic data state corresponds to a logical high.

3. The memory device of claim 1, wherein:
the fast deterministic initialization mode is a first deterministic initialization mode and the deterministic data state is a first deterministic data state;
the memory cell initialization circuitry is further configured to, upon the memory device receiving an indication to enter a second fast deterministic initialization mode, (i) couple the plurality of word line drivers to the first voltage source via the plurality of first switches such that (a) the voltage on each of the plurality of word lines is driven toward the first voltage and (b) the storage element of each of the memory cells is coupled to the corresponding one of the plurality of bit lines, and (ii) couple the plurality of bit lines to a third voltage source via the plurality of second switches such that (1) the voltage on each of the plurality of bit lines is driven toward a third voltage corresponding to a second deterministic data state and (2) the storage element of each of the plurality of memory cells is charged or discharged via the corresponding one of the plurality of bit lines to the second deterministic data state; and
the third voltage is a voltage Vss or the second deterministic data state corresponds to a logical low.

4. The memory device of claim 1, wherein the second voltage is a voltage Vss or the deterministic data state corresponds to logical low.

5. The memory device of claim 1, wherein the memory cell initialization circuitry further comprises a switch controller configured to control the plurality of first switches, the plurality of second switches, or a combination thereof.

6. The memory device of claim 5, wherein the switch controller includes a pulse generator.

7. The memory device of claim 1, wherein each of the plurality of first switches is further configured to selectively couple the corresponding one of the plurality of word line drivers to a negative word line voltage (VNWL) generator.

8. The memory device of claim 1, wherein the first voltage is a voltage Vpp.

9. The memory device of claim 1, wherein each of the plurality of second switches is further configured to selectively couple the corresponding one of the plurality of bit lines to a bit line precharge voltage (VBLP) generator.

10. A method, comprising:
receiving, at a memory device, an indication to enter a fast deterministic initialization mode,wherein the memory device includes a plurality of word lines, a plurality of bit lines,and a plurality of memory cells arranged at intersections of the plurality of word lines with the plurality of bit lines; and
based at least in part on the indication, initializing memory cells of the plurality of memory cells to a deterministic data state corresponding to the fast deterministic initialization mode.

11. The method of claim 10, wherein initializing the memory cells includes controlling the plurality of word lines such that voltages on the plurality of word lines are driven toward a first voltage and storage elements of the memory cells are coupled to bit lines of the plurality of bit lines that correspond to the memory cells.

12. The method of claim 11, wherein the deterministic data state corresponds to a logical hi_{g}h.

13. The method of claim 12, wherein:
the indication is a first indication, the fast deterministic initialization mode is a first fast deterministic initialization mode, the deterministic data state is a first deterministic
data state, the memory cells are first memory cells, the word lines are first word lines,
and the bit lines are first bit lines;
the method further comprises:receiving, at the memory device, a second indication to enter a second fast deterministic initialization mode, andbased at least in part on the second indication, initializing second memory cells of the plurality of memory cells to a second deterministic data state corresponding to the second fast deterministic initialization mode; and the second deterministic data state corresponds to a logical low.

14. The method of claim 13, wherein:
the voltages on the plurality of word lines are first voltages; and
initializing the second memory cells includes controlling the plurality of word lines such that second voltages on the plurality of word lines are driven toward the first voltage and storage elements of the second memory cells are coupled to bit lines of the plurality of bit lines that correspond to the second memory cells.

15. The method of claim 11, wherein the deterministic data state corresponds to a logical low.

16. The method of claim 11, wherein controlling the plurality of word lines includes (i) uncoupling one or more word line drivers corresponding to the plurality of word lines from one or more corresponding negative word line voltage (VNwL) generators and (ii) coupling the one or more word line drivers to a first voltage source.

17. The method of claim 10, wherein receiving the indication includes (a) receiving a command to enter the fast deterministic initialization mode at command terminals of the memory device or (b) receiving the indication via mode registers of the memory device.

18. The method of claim 10, wherein receiving the indication includes (a) receiving an indication that the memory device is performing an initialization routine or (b) receiving an indication that an internal temperature of the memory device is below a threshold temperature value.

19. A memory device, comprising:
a memory array comprising a plurality of memory cells, each memory cell of the plurality of memory cells coupled to a corresponding word line of a plurality of word lines and a corresponding bit line of a plurality of bit lines,
wherein the memory device is configured to:receive an indication to enter a fast deterministic initialization mode, andbased at least in part on the indication control one or more first switches coupled to the plurality of word lines to drive voltages on the plurality of word lines toward a first voltage such that storage elements of the plurality of memory cells are coupled to corresponding bit lines of the plurality of bit lines; and control one or more second switches coupled to the corresponding bit lines to drive voltages on the corresponding bit lines toward a second voltage such that the storage elements are written to a deterministic data state corresponding to the fast deterministic initialization mode.

20. The memory device of claim 19, wherein:
the indication is a first indication, the fast deterministic initialization mode is a first fast deterministic initialization mode, and the deterministic data state is a first deterministic data state; and
the memory device is further configured to:receive a second indication to enter a second fast deterministic initialization mode, andbased at least in part on the second indication control the one or more first switches to drive the voltages on the plurality of word lines toward the first voltage such that the storage elements of the
plurality of memory cells are coupled to the corresponding bit lines;
and control the one or more second switches coupled to the corresponding bit lines to drive the voltages on the corresponding bit lines toward a third voltage such that the storage elements are written to a second deterministic data state corresponding to the second fast deterministic initialization mode, the second deterministic data state being different from the first deterministic data state.
